(19) United States
(12) Patent Application Publication
(10) Pub. No.: US 2024/0344769 A1
(43) Pub. Date: Oct. 17, 2024

(54) FURNACE AND SEMICONDUCTOR PROCESSING EQUIPMENT

(71) Applicant: LAPLACE Renewable Energy Technology Co., Ltd., Shenzhen (CN)

(72) Inventors: Qinghua Chang, Shenzhen (CN); Tairong Zhu, Shenzhen (CN); Wu Zhang, Shenzhen (CN); Qun Liu, Shenzhen (CN)

(21) Appl. No.: 18/755,731

(22) Filed: Jun. 27, 2024

(30) Foreign Application Priority Data
Sep. 28, 2023 (CN) 202311291983.4

(51) Int. Cl. F27B 17/00; F27D 9/00

(52) U.S. Cl. CPC F27B 17/0025; F27D 9/00; F27D 2009/0005

(57) ABSTRACT

A furnace and a semiconductor processing equipment are provided. The furnace includes a furnace body and a heat exchange device, the furnace body includes a furnace tube and an insulation layer disposed around the furnace tube, a heat exchange gas channel is formed between an outer wall of the furnace tube and the insulation layer, the heat exchange gas channel includes a first gas inlet and a first gas outlet. The heat exchange device includes a gas flow channel and a cooling channel, the gas flow channel is connected to the first gas outlet, the cooling channel provides a cooling medium for exchanging heat with a gas in the gas flow channel.

### CROSS-REFERENCE TO RELATED APPLICATIONS

This application claims priority to Chinese Patent Application No. 202311291983.4 filed on Sep. 28, 2023, in China State Intellectual Property Administration, the contents of which are incorporated by reference herein.

### TECHNICAL FIELD

The present disclosure relates to the field of photovoltaic material manufacturing equipment, in particular to a furnace and a semiconductor processing equipment.

### BACKGROUND

In the manufacturing of photovoltaic cells, a raw material undergoes a series of processing (texturing, diffusion, etching, sintering, etc.) for produce a silicon wafer. Some processes require at least one high-temperature furnace. For example, the diffusion process mainly involves the reaction of boron element or phosphorus element in the process gas with silicon atoms on the surface of a silicon wafer at a high-temperature atmosphere of the high-temperature furnace, so that the boron element or the phosphorus element could diffuse into the interior of the silicon wafer. After the diffusion process, the electronic properties of the silicon wafer surface change, forming a N-type or P-type silicon wafers with different electronic energy levels, P-type photovoltaic cells with P-type silicon wafers have advantages of simple manufacturing process and low cost, while N-type photovoltaic cells with N-type silicon wafers have advantages of high efficiency and low attenuation. Users can choose different types of photovoltaic cells according to their needs. However, the temperature in a furnace body of the high-temperature furnace is so high during diffusion process, that requires a longer time cooling process after a diffusion process for preparing a next diffusion process. The long-time cooling process reduces the processing efficiency of the high-temperature furnace.

In order to solve the problems mentioned above, a solution for rapid cooling of the furnace body using compressed gas has been proposed in the related art. The solution defines a compressed gas channel in the furnace body and introduces compressed gas into the channel, so that the compressed gas absorbs the heat from the furnace body during the cooling process, and finally discharges the high-temperature compressed gas out of the furnace body to reduce the temperature in the high-temperature furnace. However, in the related art, the high-temperature compressed gas discharged from the furnace body is cooled by water spraying, it will cause the cooling water to vaporize instantly and generate a large amount of water vapor. In the actual production process, a special pipe is required for treating the large amount of water vapor, so the equipment cost required is relatively high.

### BRIEF DESCRIPTION OF THE DRAWINGS

FIG. 1 is a schematic diagram of an overall structure of a furnace of at least one embodiment of the present disclosure.

FIG. 2 is a schematic diagram of an interior structure of a furnace body of the furnace of at least one embodiment of the present disclosure.

FIG. 3 is a schematic diagram of a working principle of the furnace of at least one embodiment of the present disclosure.

FIG. 4 is a schematic diagram of an overall structure of a second heat exchanger of at least one embodiment of the present disclosure.

FIG. 5 is a schematic diagram of an interior structure of the second heat exchanger of at least one embodiment of the present disclosure.

FIG. 6 is a structural schematic diagram of heat exchange tubes of at least one embodiment of the present disclosure.

FIG. 7 is a structural schematic diagram of a first heat exchanger of at least one embodiment of the present disclosure.

FIG. 8 is a schematic diagram of an interior structure of the first heat exchanger of at least one embodiment of the present disclosure.

FIG. 9 is a front view of a fin of a fin assembly of at least one embodiment of the present disclosure.

FIG. 10 is a schematic diagram of a three-dimensional structure of the fin of the fin assembly of at least one embodiment of the present disclosure.

FIG. 11 is a partial enlarged view of the A-area as shown in FIG. 5.

FIG. 12 is a cross-sectional view of the second heat exchanger of at least one embodiment of the present disclosure.

FIG. 13 is a schematic diagram of an exterior structure of the first heat exchanger of at least one embodiment of the present disclosure.

FIG. 14 is a cross-sectional view of the first heat exchanger of FIG. 13 along B-B.

FIG. 15 is a schematic diagram of an arrangement of heat conductive bumps of at least one embodiment of the present disclosure.

FIG. 16 is a schematic diagram of an exterior structure of the first heat exchanger of at least one embodiment of the present disclosure.

FIG. 17 is a structural schematic diagram of the first heat exchanger of FIG. 16 in another angle of view.

FIG. 18 is an interior structural schematic diagram of the first heat exchanger of FIG. 16 expanded in an extension direction.

FIG. 19 is a schematic diagram of a connection relationship between a cooling medium source and a heat exchange device of at least one embodiment of the present disclosure.

FIG. 20 is a schematic diagram of a connection relationship between the cooling medium source and the heat exchange device of another embodiment of the present disclosure.

FIG. 21 is a structural schematic diagram of a device for circulating the cooling medium of at least one embodiments of the present disclosure.

FIG. 22 is a structural schematic diagram of the device for circulating the cooling medium of another embodiment of the present disclosure.

### DETAILED DESCRIPTION

In order to make the purpose, technical solutions and advantages of the embodiments of the present disclosure clearer, the technical solutions in the embodiments of the present disclosure will be described clearly and completely in conjunction with the drawings in the embodiments of the present disclosure. Based on the embodiments of the present disclosure, all other embodiments obtained by those of ordinary skill in the art without creative work shall fall within the scope of protection of the present disclosure.

Those skilled in the art should understand that, in the disclosure of the present disclosure, “at least one” refers to one or more, and multiple refers to two or more. Unless otherwise defined, all technical and scientific terms used herein have the same meaning as commonly understood by those skilled in the technical field in the present disclosure. The terminology used in the specification of present disclosure is only for the purpose of describing specific embodiments, and is not intended to limit the present disclosure.

It can be understood that, unless otherwise specified in the present disclosure, “/” means “or”. For example, A/B can mean A or B. “A and/or B” in the present disclosure is only an associative relationship describing the associated objects, which means that there can be three relationships: only A, only B, and A and B.

It can be understood that, in the disclosure of the present disclosure, the words such as “first” and “second” are only used for the purpose of distinguishing description, and cannot be understood as indicating or implying relative importance, nor as indicating or implying any order. The features defined with “first” and “second” may explicitly or implicitly include one or more of the features. In the description of the embodiments of the present disclosure, the words such as “exemplary” or “for example” are used as examples, illustrations, or indications. Any embodiment or design solution described as “exemplary” or “for example” in the embodiments of the present disclosure should not be construed as being more preferable or advantageous than other embodiments or design solutions. To be precise, the words such as “exemplary” or “for example” are used to present related concepts in a specific manner.

Those skilled in the art should understand that, in the disclosure of the present disclosure, the terms “longitudinal”, “lateral”, “upper”, “lower”, “front”, “rear”, “left”, “right”, the orientation or positional relationship indicated by “vertical”, “horizontal”, “top”, “bottom”, “inner”, “outer”, etc. are based on the orientation or positional relationship shown in the drawings, which is only for the convenience of describing the present disclosure and to simplify the description, rather than indicating or implying that the device or element referred to must have a specific orientation, or be constructed and operated in a specific orientation, so the above terms should not be understood as limiting the present disclosure.

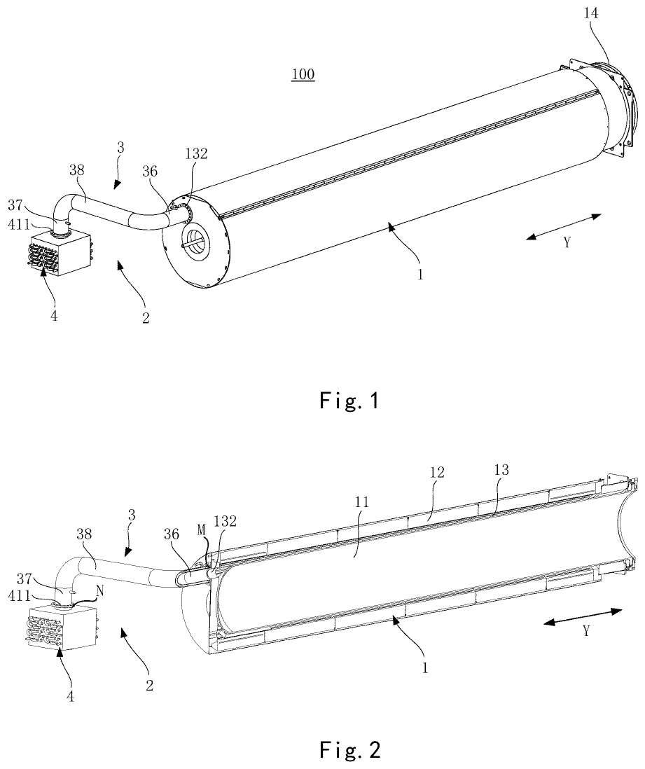

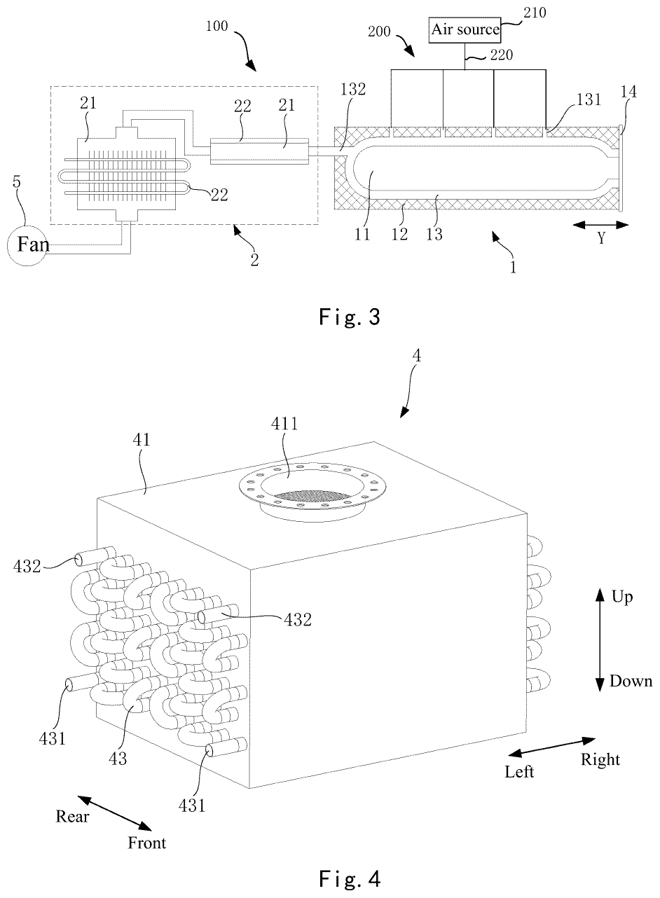

As shown in FIGS. 1, 2, and 3, FIG. 1 is a schematic diagram of an overall structure of a furnace of at least one embodiment of the present disclosure. FIG. 2 is a schematic diagram of an interior structure of a furnace body of the furnace of at least one embodiment of the present disclosure. FIG. 3 is a schematic diagram of a working principle of the furnace of at least one embodiment of the present disclosure.

A semiconductor processing equipment of at least one embodiment of the present disclosure includes a furnace 100 and a gas supply system 200.

The furnace 100 can be a diffusion furnace or other types of furnaces used in a production process of photovoltaic cells, such as a sintering furnace, a low-temperature furnace, a LPCVD reacting furnace, a PECVD reacting furnace, an oxidation furnace, etc., which will not be limited here.

The furnace 100 includes a furnace body 1 and a heat exchange device 2. The furnace body 1 includes a furnace tube 11 and an insulation layer 12 disposed around the furnace tube 11. A heat exchange gas channel 13 is formed between the insulation layer 12 and an outer wall of the furnace tube 11. The heat exchange gas channel 13 includes a first gas inlet 131 and a first gas outlet 132.

An inside of the furnace tube 11 is used to place silicon wafers and process the silicon wafers. The heat exchange gas channel 13 allows the heat exchange gas to pass through to take away part of the heat inside the furnace tube 11, thereby cooling the inside of the furnace tube 11.

The gas supply system 200 includes a gas source 210 and a gas supply line 220. The gas supply line 220 is connected between the gas source 210 and the first gas inlet 131. The gas source 210 is used to provide heat exchange gas into the heat exchange gas channel 13 through the gas supply line 220.

When in operation, the silicon wafers to be processed are firstly put into the furnace tube 11, and heating the furnace tube 11, so that an internal temperature of the furnace tube 11 gradually rises to set operating temperature (the operating temperature of some processes is higher than 1000° C.). Then, reaction gas is introduced into the furnace tube 11 and maintained for a period of time to ensure that the reaction gas fully reacts with silicon atoms on the surface of the silicon wafer; after the reaction is completed, the introduction of the reaction gas is stopped. The gas supply system 200 supplies heat exchange gas into the heat exchange gas channel 13 through the first gas inlet 131, so that the furnace tube 11 is gradually cooled to a safe temperature (it needs to be cooled to about 900° C.), and the processed silicon wafer can be taken out. The heat exchange gas can be compressed gas which is easily obtained, or it can also be other gas, such as other inert gas (carbon dioxide, nitrogen, etc.), which is not specifically limited here. Specifically, gas such as boron source, phosphorus source, and silane can be introduced into the furnace tube 11, which will not be described in detail here.

It should be noted that the furnace tube 11 can be a quartz tube, but it is not limited thereto, for example, it can also be a silicon nitride tube, an alumina tube, or a high-temperature alloy tube. A heat insulation layer outside the furnace tube 11 is formed by the insulation layer 12 set on the periphery of the furnace tube 11, the heat loss in a high-temperature environment can be reduced, so as to ensure that the process is carried out under a constant high temperature condition. The material of the insulation layer 12 can be ceramic fiber or aluminum silicate, etc., which is not specifically limited here.

The heat exchange device 2 includes a gas flow channel 21 and a cooling channel 22. The gas flow channel 21 is connected to the first gas outlet 132. The cooling channel 22 is used to provide a cooling medium, and the cooling medium is used to exchange heat with the gas in the gas flow channel 21. That is, the temperature of the heat exchange gas increases after absorbing part of the heat inside the furnace tube 11 in the heat exchange gas channel 13, and then the heat exchange gas is discharged from the first gas outlet 132 into the gas flow channel 21 of the heat exchange device 2 for a secondary heat exchange.

The cooling medium provided in the cooling channel 22 of the heat exchange device 2 is used to exchange heat with the heat exchange gas in the gas flow channel 21, so that the heat exchange gas is cooled and discharged. The cooling medium may be a flowable cooling medium, such as cooling water, low-temperature kerosene, etc., but it is not limited to this. The cooling medium may also be a non-flowing cooling medium, such as solid coolant (such as dry ice and water ice), the solid coolant sublimates during heat exchange to remove heat from the heat exchange gas.

The furnace 100 provided in the embodiment of the present disclosure can further cool the heat exchange gas discharged from the heat exchange gas channel 13 by arranging the heat exchange device 2. Compared with a cooling method of processing water spraying to the heat exchange gas in the related art, the heat exchange device 2 is provided with the gas flow channel 21 for the circulation of heat exchange gas and the cooling flow channel 22 for the circulation of cooling medium, and the cooling medium is sufficient to ensure that only the heat exchange gas is absorbed during the heat exchange process without phase change. It can be seen that the solution of arranging the heat exchange device 2 reduces gathering a large amount of water vapor, so the furnace 100 is free of a dedicated water vapor treatment pipeline. A cooling efficiency of the furnace body 1 and a processing efficiency of the furnace 100 are improved.

A number of the first gas inlet 131 is not limited to one. As shown in FIG. 3, in some embodiments, a plurality of first gas inlets 131 are provided on the outer peripheral wall of the furnace body 1. The plurality of first gas inlets 131 are arranged at intervals along a length direction Y of the furnace body 1, each first gas inlet 131 is connected to the heat exchange gas channel 13. The gas source 210 is communicated to one of the plurality of first gas inlets 131 through one of a plurality of gas supply lines 220.

Through such an arrangement, the heat exchange gas can simultaneously enter an inside of the heat exchange gas channel 13 through the plurality of first gas inlets 131. In addition, the plurality of first gas inlets 131 are arranged at intervals along the length direction Y of the furnace body 1, so that, the heat exchange gas can be more evenly distributed throughout the inside of the heat exchange gas channel 13, which is conducive to improving the heat exchange effect of the heat exchange gas inside the heat exchange gas channel 13, and thus is conducive to ensuring the cooling effect inside the furnace tube 11.

As shown in FIG. 3, in some embodiments, the furnace 100 further includes a suction device 5. The suction device 5 is connected to an outlet of the gas flow channel 21 of the heat exchange device 2. A suction flow rate of the suction device 5 is greater than a gas inlet flow rate of the first gas inlet 131. The suction device 5 can be an exhaust fan (also named as a fan), a gas pump, etc., which is not specifically limited here.

By adjusting the suction flow rate of the suction device 5 to be greater than the inlet flow rate of the first gas inlet 131, a fluidity of the heat exchange gas inside the heat exchange gas channel 13 and the heat exchange device 2 can be ensured, and a situation that the heat exchange gas and the temperature inside the furnace tube 11 reach equilibrium due to the untimely discharge of the heat exchange device 2 can be prevented, which is beneficial to improving the heat exchange efficiency of the heat exchange gas channel 13 and the heat exchange device 2, thereby improving the cooling efficiency of the furnace body 1.

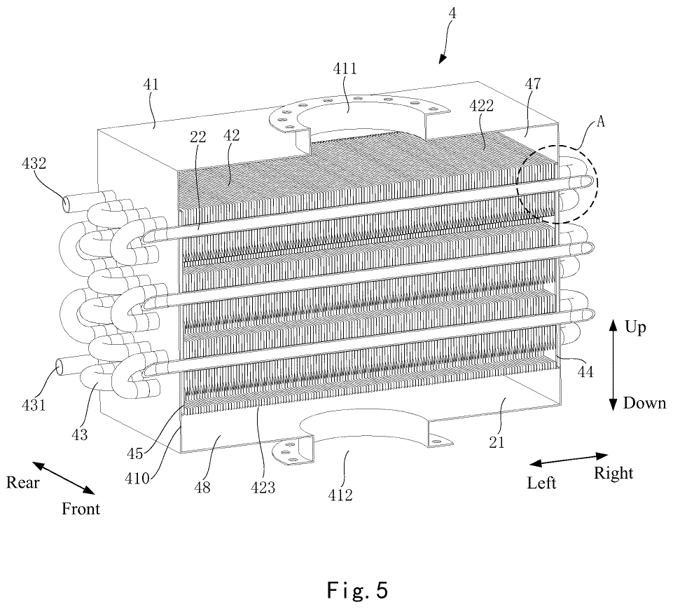

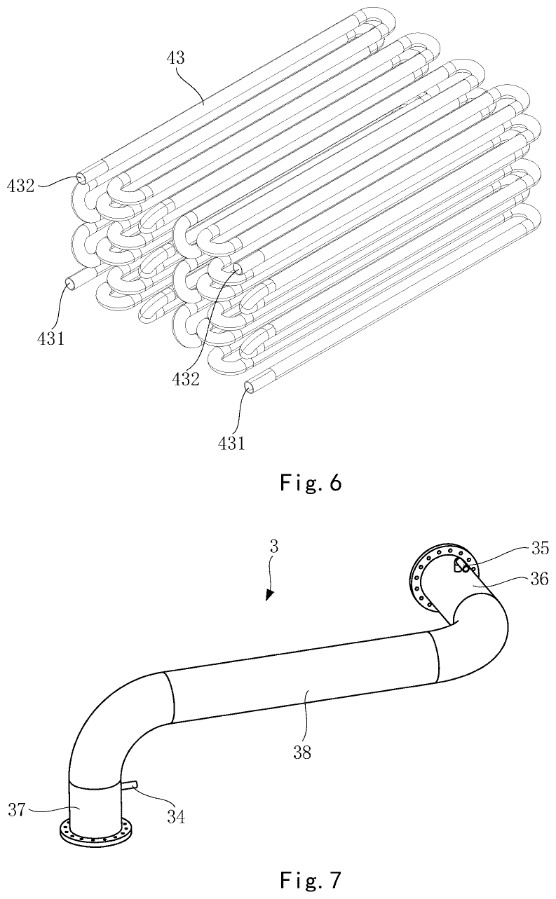

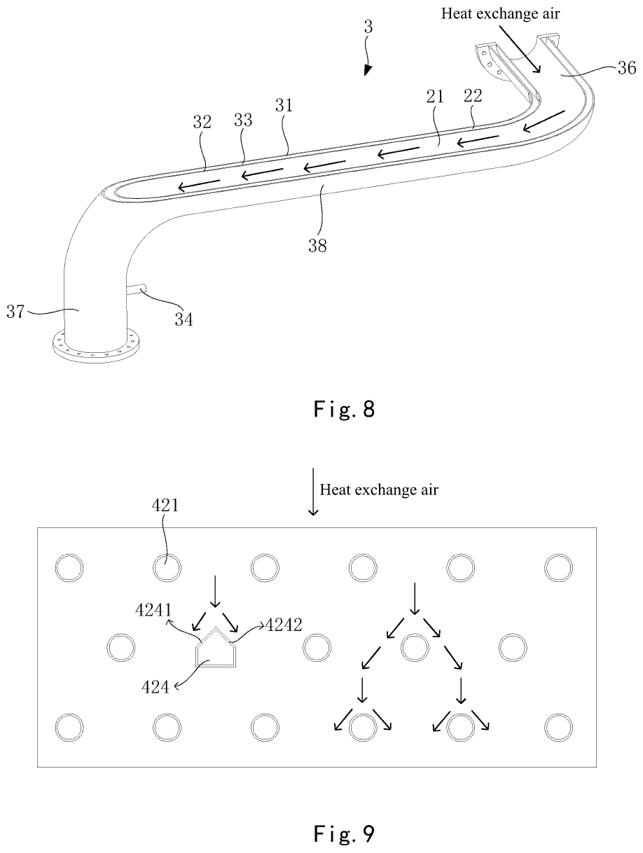

As shown in FIGS. 1 and 4 to 8, FIG. 4 is a schematic diagram of an overall structure of a second heat exchanger of at least one embodiment of the present disclosure, FIG. 5 is a schematic diagram of an interior structure of the second heat exchanger of at least one embodiment of the present disclosure, FIG. 6 is a structural schematic diagram of heat exchange tubes of at least one embodiment of the present disclosure, FIG. 7 is a structural schematic diagram of a first heat exchanger of at least one embodiment of the present disclosure, and FIG. 8 is a schematic diagram of an interior structure of the first heat exchanger of at least one embodiment of the present disclosure. In some embodiments, the heat exchange device 2 includes a first heat exchanger 3 and a second heat exchanger 4. The second heat exchanger 4 includes a housing 41, a fin assembly 42 located inside the housing 41, and a plurality of heat exchange tubes 43 passing through mounting holes 421 (shown in FIG. 9) of the fin assembly 42. The housing 41 includes a second gas inlet 411 and a second gas outlet 412. The first heat exchanger 3 includes an outer tube 31 and an inner tube 32 passing through the outer tube 31. A first gap 33 is formed between the outer tube 31 and the inner tube 32. The inner tube 32 is connected between the second gas inlet 411 and the first gas outlet 132, the inner tube 32 and an inner space of the housing 41 form the gas flow channel 21; the first gap 33 and the heat exchange tube 43 are both the cooling channel 22.

By arranging the heat exchange device 2 as a two-stage heat exchange structure including the first heat exchanger 3 and the second heat exchanger 4, the heat exchange gas is discharged from the first gas outlet 132 and then enters the inner tube 32 and the housing 41 in sequence, and exchanges heat with the cooling medium in the first gap 33 and the heat exchange tube 43, so as to reduce the temperature of the heat exchange gas. In this way, compared with only providing a single type of heat exchange device, the first heat exchanger 3 and the second heat exchanger 4 in this embodiment can cool the heat exchange gas twice, which is beneficial to improving the heat exchange efficiency and the heat exchange effect of the heat exchange device 2.

The first heat exchanger 3 is arranged between the furnace body 1 and the second heat exchanger 4, the first heat exchanger 3 is connected to the first gas outlet 132 of the furnace body 1 and the second gas inlet 411 of the second heat exchanger 4. Thus, the first heat exchanger 3 not only has a function of transmitting the heat exchange gas from the furnace body 1 to the second heat exchanger 4, so, the furnace body 1 is free of a gas pipeline for connecting the second heat exchanger 4. The cooling medium in the first gap 33 can also reduce the temperature of the heat exchange gas.

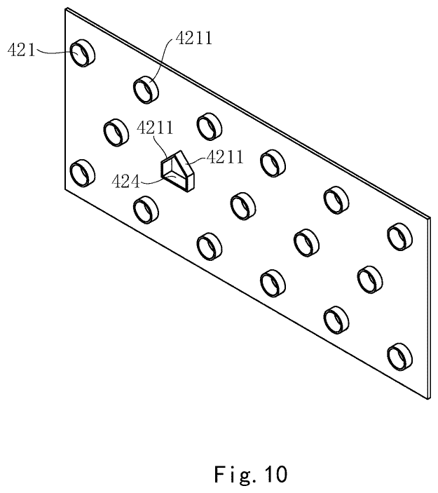

As shown in FIGS. 9 and 10, FIG. 9 is a front view of a fin of a fin assembly of at least one embodiment of the present disclosure, FIG. 10 is a schematic diagram of a three-dimensional structure of the fin of the fin assembly of at least one embodiment of the present disclosure. A plurality of mounting holes 421 are defined on the fin, the heat exchange tube 43 is arranged in the mounting holes 421. The fin is provided with multiple rows of mounting hole arrays, each row of mounting hole arrays includes a plurality of mounting holes 421. The multiple mounting holes 421 in adjacent rows of mounting hole arrays are in misaligned arrangement. Thus, when the gas flows from top to bottom to each heat exchange tube 43, the gas will be dispersed to the left and right sides. That is, the misaligned arrangement of the heat exchange tube 43 is conducive to dispersing a flow direction of the gas and increasing a contact area between the gas and the heat exchange tube 43. The heat exchange tube 43 can be connected to the fin assembly 42 as a whole at the mounting holes 421 by expanding the tube or brazing, and the connection process is not specifically limited here.

As shown in FIGS. 9, 10, and 11, FIG. 11 is a partial enlarged view of the A-area as shown in FIG. 5. In some embodiments, the fin assembly 42 is formed by an arrangement of a plurality of fins. A flange 4211 extends from a hole wall of the mounting hole 421 on the fin in the fin assembly 42. The flange 4211 extends along an arrangement direction of the fins in the fin assembly 42, and surrounds the outer peripheral surface of the heat exchange tube 43. By providing the flange 4211, a certain distance can be maintained between adjacent fins, which facilitates mounting and fixed connection; at the same time, it also increases a support strength of the heat exchange tube 43 by the mounting holes 421 in the fins in the fin assembly 42. A height of the flange 4211, that is, a distance between adjacent fins, can be 2 millimeters (mm) to 5 mm.

As shown in FIGS. 9 and 10, a quantity of the heat exchange tube can be confirmed according to a heat exchange area, heat exchange tube specifications, and a layout of the mounting holes 421 on the fin in the fin assembly 42 can be confirmed according to the quantity of the heat exchange tube. As a quantity of the mounting holes 421 is confirmed, an avoidance hole 424 needs to be defined in a spare position of the fin. A first side 4241 and a second side 4242 of the avoidance hole 424 facing a gas inflow direction form an acute angle and extend along the arrangement direction of the fins in the fin assembly 42 to form the flange 4211, in this way, the gas can be dispersed to the left and right sides when it flows from top to bottom to the avoidance hole 424, which is beneficial to improving an uniformity of gas distribution.

The heat exchange tube 43, the fin assembly 42 and the housing 41 can be made of copper, but are not limited to this. For example, the heat exchange tube 43 and the fin assembly 42 can be made of copper, and the housing 41 can be made of stainless steel; or the heat exchange tube 43, the fin assembly 42 and the housing 41 can be all made of stainless steel, which may be determined according to the actual situation.

As shown in FIGS. 4, 5, and 6, in some embodiments, the heat exchange tube 43 includes at least one first inlet 431 and at least one first outlet 432. The first inlet 431 is located lower than the first outlet 432. That is: an inlet position of the cooling medium is lower than an outlet position of the cooling medium.

With such an arrangement, during the operation of the second heat exchanger 4, taking the cooling medium as cooling water as an example, when the inlet position of the cooling water is lower than the outlet position, that is, the cooling water is injected into the heat exchange tube 43 from a low position, so as to effectively discharge excess gas inside the heat exchange tube 43 and avoid gas holes in the cooling water inside the heat exchange tube 43. That is, the inside of the heat exchange tube 43 can be evenly filled with the cooling water, which is beneficial to improving the heat exchange uniformity and heat exchange efficiency of the second heat exchanger 4 and thereby speeding up the cooling speed of the furnace body 1.

The heat exchange tube 43 is a serpentine tube as a whole, including at least two straight tube sections and at least one elbow section. The first inlet 431 and the first outlet 432 are provided at ends of the two straight tube sections, respectively. An elbow section connects two straight tube sections located on a same side. The heat exchange tube 43 includes multiple rows of straight tube section arrays, each row of straight tube section arrays includes multiple straight tube sections, and the multiple straight tube sections in two adjacent rows of straight tube section arrays are disposed in a misaligned arrangement. In this way, it is beneficial to increasing the quantity of the heat exchange tube 43 while occupying a same space, and dispersing the gas to form a flow around the outside of the heat exchange tube 43, which is beneficial to improving a heat transfer coefficient and enhancing the heat exchange effect.

It should be noted that the quantity of the first inlet 431 and the first outlet 432 of the heat exchange tube 43 is not limited to one pair, and may also be provided as multiple pairs. As shown in FIGS. 4 and 6, the heat exchange tube 43 has two pairs of the first inlets 431 and the first outlets 432. That is, the heat exchange tube 43 is composed of two groups of heat exchange tube units, and each group of heat exchange tube units has a pair of the first inlets 431 and the first outlets 432. In this way, it is beneficial to increasing a flow rate of the cooling medium in the heat exchange tube 43 and further improving the heat exchange effect.

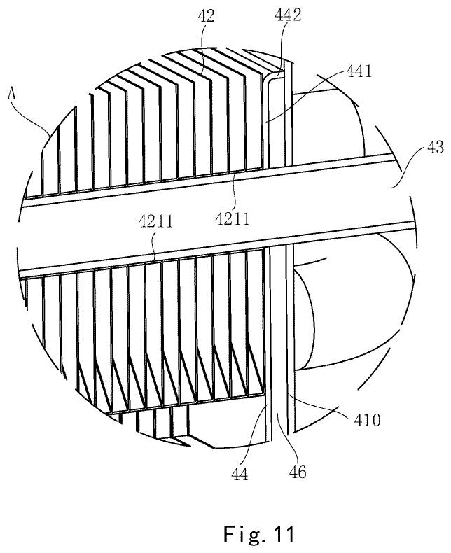

As shown in FIGS. 5 and 11, in some embodiments, an inner wall 410 of the housing 41 is provided with a first fixing plate 44 and a second fixing plate 45. The first fixing plate 44 and the second fixing plate 45 are arranged apart along the arrangement direction of the fins in the fin assembly 42. The fin assembly 42 is disposed in the space between the first fixing plate 44 and the second fixing plate 45.

Through such an arrangement, the fin assembly 42 can have a certain limiting effect along the arrangement direction of the fins in the fin assembly 42. During the operation of the second heat exchanger 4, since the internal space of the housing 41 is a gas flow channel, the fin assembly 42 inside the housing 41 will be affected by the gas flow and cause shaking or movement, and the first fixed plate 44 and the second fixed plate 45 are respectively arranged on both sides of the fin assembly 42 along the fin arrangement direction, which limits the movement of the fin assembly 42 in this direction, which is beneficial to ensuring a normal operation and extension a usage life of the second heat exchanger 4.

As shown in FIG. 11, in some embodiments, the first fixing plate 44 includes a connecting wall 441 and a protrusion 442 arranged at an edge of the connecting wall 441. The second fixing plate 45 also includes a connecting wall 441 and a protrusion 442 arranged at an edge of the connecting wall 441. The connecting wall 441 abuts the fin assembly 42, and the protrusion 442 is in contact with the fin assembly 42. The protrusion 442 is in contact with the inner wall 410 of the housing 41, and a second gap 46 is formed between the connecting wall 441 and the inner wall 410 of the housing 41.

Through the formation of the second gap 46, the second gap 46 plays a certain thermal insulation role during the operation of the second heat exchanger 4, which is beneficial to reducing heat transfer and heat loss inside the housing 41 of the second heat exchanger 4, and improving a stability of the heat exchange effect inside the housing 41, and further improving a temperature stability and a control accuracy of the furnace tube 11 during the cooling process.

As shown in FIG. 5, in some embodiments, the second gas inlet 411 and the second gas outlet 412 are respectively provided on opposite sides of the housing 41. A first diffusion space 47 is formed between the second gas inlet 411 and a gas inlet surface 422 of the fin assembly 42. A second diffusion space 48 is formed between the second gas outlet 412 and a gas outlet surface 423 of the fin assembly 42.

By providing the first diffusion space 47 and the second diffusion space 48, sufficient movement space can be provided for the flow of heat exchange gas in the housing 41 to ensure that the heat exchange gas can be evenly diffused and transmitted to each part of the fin assembly 42, avoiding that the heat exchange gas cannot be diffused and only contacts the fins at the opposite positions of the second gas inlet 411 and the second gas outlet 412, which is beneficial to increasing the contact area between the heat exchange gas and the fins in the fin assembly 42, and improving the heat transfer efficiency and the cooling efficiency of the furnace body 1.

As shown in FIG. 5, the second gas inlet 411 and the second gas outlet 412 can be located on the upper and lower sides of the housing 41 respectively, but not limited to this, the second gas inlet 411 and the second gas outlet 412 may also be provided on the left and right sides or the front and rear sides of the housing 41, depending on the actual situation.

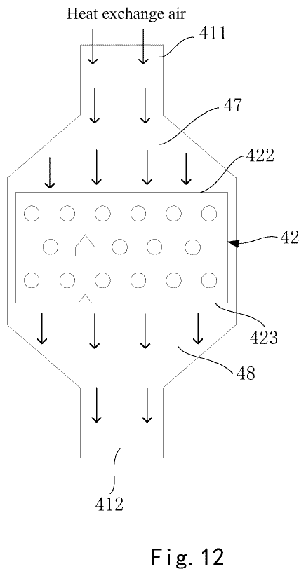

As shown in FIG. 12, FIG. 12 is a cross-sectional view of the second heat exchanger of at least one embodiment of the present disclosure. In some embodiments, along a direction from the second gas inlet 411 to the fin assembly 42, the first diffusion space 47 is in an expanded shape.

Through such an arrangement, the heat exchange gas gradually increases in the first diffusion space 47 from the second gas inlet 411 to the gas inlet surface 422 of the fin assembly 42, and the heat exchange gas can be guided to edges on both sides of the gas inlet surface 422 of the fin assembly 42, ensuring that the heat exchange gas is evenly dispersed to various positions of the gas inlet surface 422, which is beneficial to increasing the contact area between the heat exchange gas and the fins and improving the heat exchange efficiency.

As shown in FIG. 12, in some embodiments, along a direction from the fin assembly 42 to the second gas outlet 412, the second diffusion space 48 is in a constriction shape.

Through such an arrangement, a space of the heat exchange gas flowing out of the second gas outlet 412 is limited, thereby increasing the gas flow speed, which is conducive to improving the fluidity of the gas, so that the heat exchange gas can quickly flow through the second gas outlet 412 after the heat exchange inside the housing 41 is completed, and further improving the heat exchange efficiency.

It should be noted that the second heat exchanger 4 in the heat exchange device 2 can also be replaced by a fixed tube plate heat exchanger, a U-shaped tube heat exchanger, a floating head heat exchanger, etc., which is not specifically limited here.

As shown in FIGS. 7 and 8, in some embodiments, an outer surface of the outer tube 31 of the first heat exchanger 3 is provided with a second inlet 34 and a second outlet 35. The second inlet 34 and the second outlet 35 are respectively connected to the first gap 33. A position of the second inlet 34 is lower than a position of the second outlet 35. That is, the second inlet 34 and the second outlet 35 are respectively the inlet and outlet of the cooling medium in the first heat exchanger 3.

By setting the position of the second inlet 34 lower than the position of the second outlet 35, the cooling medium in the first heat exchanger 3 can flow from low to high. In this way, effectively avoiding an occurrence of gas cavities when the cooling medium is introduced into the first gap 33, thus improving the heat exchange uniformity and heat exchange efficiency.

As shown in FIGS. 1 and 7, in some embodiments, one end of the furnace body 1 is provided with a furnace door 14, and another end of the furnace body 1 is provided with the first gas outlet 132. The first heat exchanger 3, along its extension direction, includes a first connecting section 36, a second connecting section 37, and a main body section 38 between the first connecting section 36 and the second connecting section 37. The first connecting section 36 is connected to the first gas outlet 132, the second connecting section 37 is connected to the second gas inlet 411, and a position of the second gas inlet 411 is lower than a position of the first gas outlet 132. The second inlet 34 is arranged on the second connecting section 37, and the second outlet 35 is arranged on the first connecting section 36.

By arranging the second inlet 34 on the second connecting section 37 and the second outlet 35 on the first connecting section 36, that is, the inlet and outlet of the cooling medium are arranged on both ends of the first heat exchanger 3 along an extension direction. In this way, it can be ensured that the cooling medium fills the inside of the first gap 33 along the extension direction of the first heat exchanger 3, avoiding a situation that the heat exchange effect is weakened due to the absence of cooling medium at the edges of the first gap 33, and is conducive to improving the heat exchanger efficiency and cooling efficiency of furnace body 1.

Furthermore, as shown in FIG. 7, in some embodiments, the second outlet 35 is arranged on a top of the first connecting section 36.

Through such an arrangement, the cooling medium can be filled in the inside of the first gap 33, preventing the cooling medium from being unable to reach a top inner surface of the first connecting section 36 due to its own gravity when flowing, effectively avoiding waste of space and improving heat exchange efficiency.

As shown in FIG. 1, in some embodiments, the main body section 38 extends toward a peripheral side of the furnace body 1. The peripheral side of the furnace body 1 refers to any side away from the outer peripheral wall of the furnace body 1 along a radial direction of the furnace body 1.

Through such an arrangement, the first heat exchanger 3 and the second heat exchanger 4 connected to the first heat exchanger 3 can be arranged on the peripheral side of the furnace body 1 without occupying an additional position on the side of the first gas outlet 132 of the furnace body 1, avoiding impacts of the heat exchange device 2 on other pipelines connected to the furnace body 1, which is conducive to rational use of space and reduces the cost of layout design in actual application sites.

Furthermore, as shown in FIGS. 1 and 7, in some embodiments, central axes of each of the first connecting section 36 and the second connecting section 37 are noncoplanar straight lines, the first connecting section 36 extends along the length direction Y of the furnace body 1, and an extension direction of the second connecting section 37 is perpendicular with an extension direction of the first connecting section 36.

By arranging the central axes of the first connecting section 36 and the second connecting section 37 to be in noncoplanar straight line relationship, such an arrangement can satisfy the main body section 38 extending towards the peripheral side of the furnace body 1; at the same time, the heat exchange gas and the cooling medium are caused to change the flow direction multiple times when flowing inside the first heat exchanger 3, thus reducing the flow speed of the heat exchange gas and the cooling medium and extending their residence time inside the first heat exchanger 3, so that the heat exchange gas and the cooling medium can fully exchange heat.

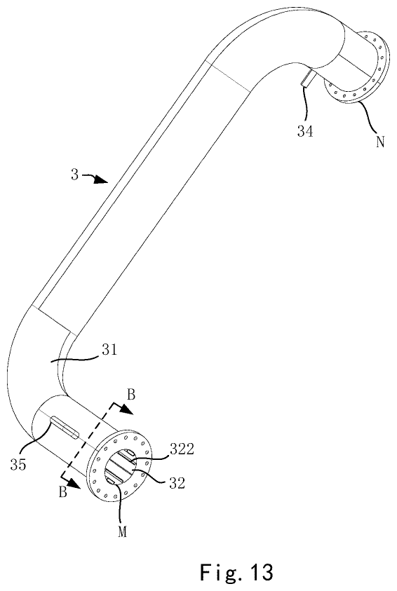

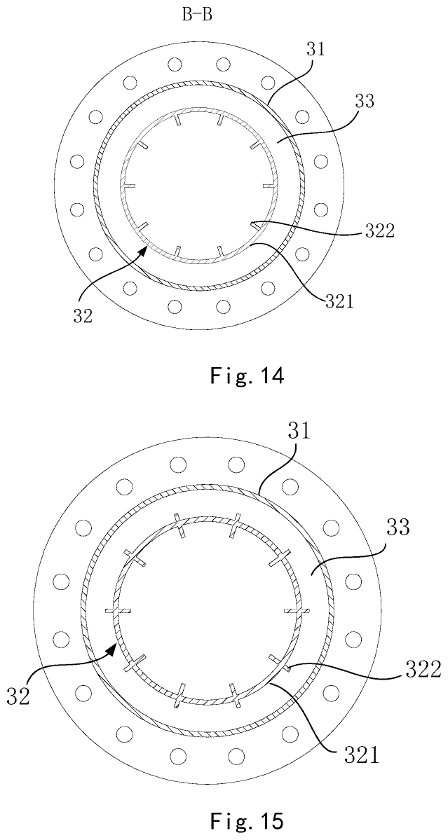

In some embodiments, as shown in FIGS. 13 and 14, FIG. 13 is a schematic diagram of an exterior structure of the first heat exchanger of at least one embodiment of the present disclosure, FIG. 14 is a cross-sectional view of the first heat exchanger of FIG. 13 along B-B. The inner tube 32 includes a tube wall 321 and heat-conducting protrusions 322 disposed on the tube wall 321. The heat-conducting protrusions 322 protrude from an inner surface of the tube wall 321 and extends along an extension direction of the inner tube 32. By this arrangement, the heat-conducting protrusions 322 can increase a contact area between the inner tube 32 and the heat exchange gas inside, so that the heat exchange gas can fully transfer heat to the cooling medium in the first gap 33, facilitating the cooling of the heat exchange gas.

The heat-conducting protrusions 322 protruding from the inner surface of the tube wall 321 may be the heat-conducting protrusions 322 entirely protrude from the inner surface of the tube wall 321, or partially protrude from the inner surface of the tube wall 321, which is no specific limitation here.

In some embodiments, the heat-conducting protrusions 322 protrude from an outer surface of the tube wall 321 and extend along the extension direction of the inner tube 32. This arrangement increases a contact area between the inner tube 32 and the cooling medium in the first gap 33, so that the heat exchange gas can fully transfer heat to the cooling medium in the first gap 33, thereby facilitating the cooling of the heat exchange gas.

The heat-conducting protrusions 322 protruding from the outer surface of the tube wall 321 may be the heat-conducting protrusions 322 entirely protrude from the outer surface of the tube wall 321, or partially protrude from the outer surface of the tube wall 321, which is no specific limitation here.

In some embodiments, as shown in FIG. 15, FIG. 15 is a schematic diagram of an arrangement of heat conductive bumps of at least one embodiment of the present disclosure.

There is a part of the heat-conducting protrusions 322 protrude from the inner surface of the tube wall 321 and extends along the extension direction of the inner tube 32. There is also a part of the heat-conducting protrusions 322 protrude from the outer surface of the tube wall 321 and extends along the extension direction of the inner tube 32. Such an arrangement increases the contact area between the inner tube 32 and the heat exchange gas, and increases the contact area between the inner tube 32 and the cooling medium in the first gap 33, so that the heat exchange gas can more fully transfer heat to the cooling medium in the first gap 33, which is more conducive to cooling the heat exchange gas.

In some embodiments, as shown in FIGS. 14 and 15, a quantity of the heat-conducting protrusions 322 is multiple (for example, 10), and the plurality of heat-conducting protrusions 322 are arranged at intervals along a circumferential direction of the inner tube 32. By this arrangement, the contact area between the inner tube 32, the heat exchange gas, and the cooling medium can be increased in the circumferential direction of the inner tube 32, so that the heat exchange gas can fully transfer heat to the cooling medium in the first gap 33, which is more conducive to the cooling of the heat exchange gas.

In some embodiments, as shown in FIGS. 2 and 13, one end of the heat-conducting protrusions 322 extends to a gas inlet end M of the inner tube 32, another of the heat-conducting protrusions 322 extends to a gas outlet end N of the inner tube 32. That is, opposite ends of the heat-conducting protrusions 322 respectively extend to the ends of the inner tube 32. By this arrangement, the contact area between the inner tube 32 and the heat exchange gas and the cooling medium can be increased in the extension direction of the inner tube 32, so that the heat exchange gas can fully transfer heat to the cooling medium in the first gap 33, thereby it is more conducive to cooling the heat exchange gas.

As shown in FIG. 2, the gas inlet end M of the inner tube 32 is the end of the inner tube 32 connected to the first gas outlet 132, the gas outlet end N of the inner tube 32 is the end of the inner tube 32 connected to the second gas inlet 411.

In some embodiments, as shown in FIGS. 13 and 14, the heat-conducting protrusions 322 are heat conductive ribs, which is not limited to this, and the heat-conducting protrusions 322 can also be configured in other structures according to actual conditions.

In some embodiments, as shown in FIGS. 14 and 15, the heat-conducting protrusions 322 and the tube wall 321 are integrated structures, which is not limited to this, the heat-conducting protrusions 322 and the tube wall 321 can also be separated.

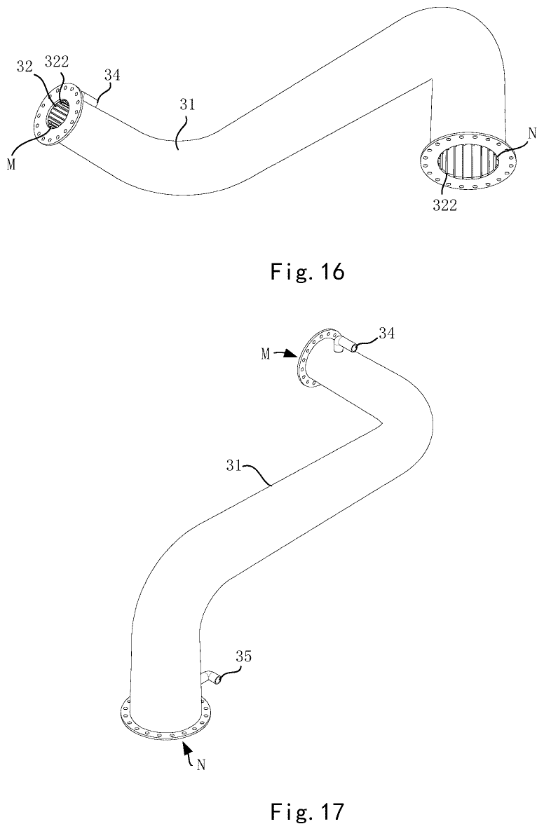

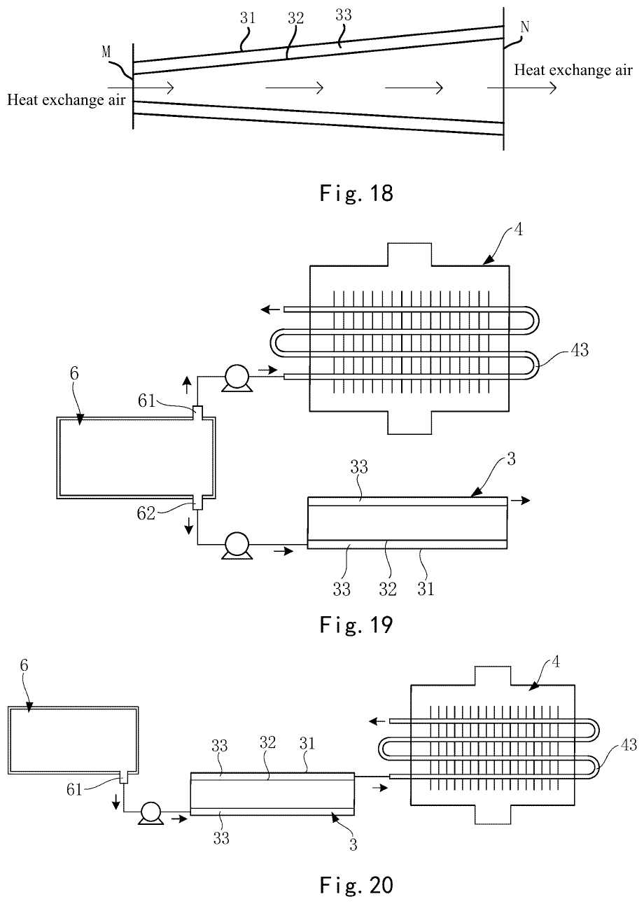

In some embodiments, as shown in FIGS. 1, 16, 17, and 18, FIG. 16 is a schematic diagram of an exterior structure of the first heat exchanger of at least one embodiment of the present disclosure, FIG. 17 is a structural schematic diagram of the first heat exchanger of FIG. 16 in another angle of view, FIG. 18 is an interior structural schematic diagram of the first heat exchanger of FIG. 16 expanded in an extension direction. Along the extension direction of the inner tube 32 and from the gas inlet end M to the gas outlet end N of the inner tube 32, a diameter of the inner tube 32 gradually increases, that is, along the flow direction of the heat exchange gas in the inner tube 32 (in the direction of the arrow as shown in FIG. 18), the diameter of the inner tube 32 gradually increases.

By this arrangement, when the heat exchange gas flows through the inner tube 32 of the first heat exchanger 3, the heat exchange gas gradually flows from the small space to the large space, a volume of the heat exchange gas will gradually expand. In the process of expansion, the heat exchange gas will release part of the heat, which is beneficial to the cooling of the heat exchange gas.

In some embodiments, as shown in FIGS. 16, 17, and 18, along the extension direction of the inner tube 32 and from the gas inlet end M to the gas outlet end N of the inner tube 32, a diameter of the outer tube 31 gradually increases. By this arrangement, a size of the first gap 33 can be kept constant in the extension direction of the inner tube 32, so that the first gap 33 can be filled easily when the cooling medium flows in the first gap 33, which is beneficial to the heat exchange between the cooling medium and the heat exchange gas.

The inner tube 32 and the outer tube 31 of the first heat exchanger 3 can be formed by curling sector plates. When the first heat exchanger 3 includes the first connecting section 36, the second connecting section 37, and the main body section 38, the first heat exchanger 3 can be manufactured in sections and then assembled together.

As shown in FIG. 19, FIG. 19 is a schematic diagram of a connection relationship between a cooling medium source and a heat exchange device of at least one embodiment of the present disclosure. In some embodiments, the furnace 100 further includes a cooling medium source 6 for outputting the cooling medium. The cooling medium source 6 includes a first output port 61 and a second output port 62. The first output port 61 is connected to the heat exchange tube 43, the second output port 62 is connected to the first gap 33. That is, the heat exchange tube 43 and the first gap 33 are two independent cooling channels 22 arranged in parallel. The cooling medium enters the heat exchange tube 43 and the first gap 33 to perform heat exchange respectively. The cooling medium are discharged from the outlet of the heat exchange tube 43 and the outlet of the first gap 33 respectively after the heat exchange is completed.

By this arrangement, the cooling medium flowing into the heat exchange tube 43 and the first gap 33 has not undergone heat exchange, and can provide better cooling effect for the heat exchange gas in the first heat exchanger 3 and the second heat exchanger 4 respectively.

As shown in FIG. 20, FIG. 20 is a schematic diagram of a connection relationship between the cooling medium source and the heat exchange device of another embodiment of the present disclosure. In other embodiments, the cooling medium outputted from the first output port 61 of the cooling medium source 6 is used sequentially inside the first gap 33 and the heat exchange tube 43. The cooling medium first flows into the first gap 33, and heat exchange occurs inside the first gap 33. Then, the cooling medium flows into the inside of the heat exchange tube 43 and is finally discharged from the outlet of the heat exchange tube 43. That is, the heat exchange tube 43 and the first gap 33 are connected cooling channels 22 arranged in series. Such a design makes a connection relationship between the cooling medium source and the heat exchange device simpler, which is conducive to simplifying the equipment structure and reducing production costs.

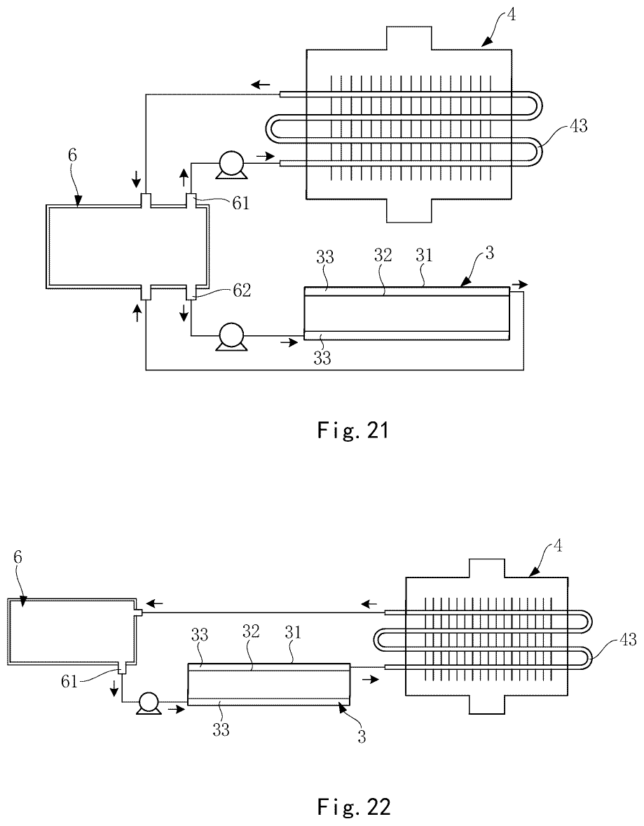

In addition, the cooling medium after heat exchange can be recycled to improve the utilization rate of the cooling medium and reduce production costs. As shown in FIGS. 21 and 22, FIG. 21 is a structural schematic diagram of a device for circulating the cooling medium of at least one embodiments of the present disclosure, FIG. 22 is a structural schematic diagram of the device for circulating the cooling medium of another embodiment of the present disclosure.

Taking the cooling medium as water as an example, the cooling medium source 6 may be a water storage tank or a water storage box. When the heat exchange tube 43 and the first gap 33 are two independent cooling channels 22 arranged in parallel (as shown in FIG. 15), the water storage tank or water storage box is driven by a hydraulic pump or a pneumatic pump, the cooling water is transported to the inside of the heat exchange tube 43 and the first gap 33 respectively, so that the cooling water performs heat exchange inside the heat exchange tube 43 and the first gap 33 respectively. The cooling water returns to the water storage tank or water storage box for recycling after the heat exchange is completed. When the heat exchange tube 43 and the first gap 33 are connected cooling channels 22 arranged in series (as shown in FIG. 16), the cooling water is driven into the first gap 33 and the heat exchange tube 43 by the hydraulic pump or the pneumatic pump. The cooling water is discharged from the outlet of the heat exchange tube 43 and flows back to the water storage tank or the water storage box after the heat exchange is completed, so that the cooling water can be recycled.

Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

What is claimed is:

1. A furnace comprising:
a furnace body comprising a furnace tube and an insulation layer disposed around the furnace tube, a heat exchange gas channel formed between an outer wall of the furnace tube and the insulation layer, the heat exchange gas channel comprising a first gas inlet and a first gas outlet; and
a heat exchange device comprising a gas flow channel and a cooling channel, the gas flow channel connected to the first gas outlet, the cooling channel configured to provide a cooling medium for exchanging heat with a gas in the gas flow channel.

2. The furnace according to claim 1, wherein the heat exchange device comprises a first heat exchanger and a second heat exchanger;
the second heat exchanger comprises a housing, a fin assembly located inside the housing, and a plurality of heat exchange tubes passing through mounting holes of the fin assembly, the housing comprises a second gas inlet and a second gas outlet, each of the plurality of heat exchange tube comprises a first inlet and a first outlet, the first inlet is located lower than the first outlet;
the first heat exchanger comprises an outer tube and an inner tube passing through the outer tube, a first gap is formed between the outer tube and the inner tube, the inner tube is connected between the second gas inlet and the first gas outlet, the inner tube and an inner space of the housing form the gas flow channel, the first gap and the heat exchange tube are both the cooling channel.

3. The furnace according to claim 2, wherein an inner wall of the housing is provided with a first fixing plate and a second fixing plate, the first fixing plate and the second fixing plate are arranged apart along an arrangement direction of fins in the fin assembly, the fin assembly is disposed between the first fixing plate and the second fixing plate.

4. The furnace according to claim 3, wherein each of the first fixing plate and the second fixing plate comprises a connecting wall and a protrusion arranged at an edge of the connecting wall, the connecting wall abuts the fin assembly, the protrusion is in contact with the inner wall of the housing, a second gap is formed between the connecting wall and the inner wall of the housing.

5. The furnace according to claim 2, wherein the second gas inlet and the second gas outlet are respectively provided on opposite sides of the housing, a first diffusion space is formed between the second gas inlet and a gas inlet surface of the fin assembly, a second diffusion space is formed between the second gas outlet and a gas outlet surface of the fin assembly.

6. The furnace according to claim 5, wherein along a direction from the second gas inlet to the fin assembly, the first diffusion space is in an expanded shape; and/or
along a direction from the fin assembly to the second gas outlet, the second diffusion space is in a constriction shape.

7. The furnace according to claim 2, wherein along an extension direction of the inner tube and from a gas inlet end to a gas outlet end of the inner tube, a diameter of the inner tube gradually increases.

8. The furnace according to claim 7, wherein along the extension direction of the inner tube and from the gas inlet end to the gas outlet end of the inner tube, a diameter of the outer tube gradually increases.

9. The furnace according to claim 2, wherein the inner tube comprises a tube wall and a plurality of heat-conducting protrusions disposed on the tube wall;
at least a part of the plurality of heat-conducting protrusions protrude from an inner surface of the tube wall and extend along an extension direction of the inner tube; and/or
at least a part of the plurality of heat-conducting protrusions protrude from an outer surface of the tube wall and extend along the extension direction of the inner tube.

10. The furnace according to claim 9, wherein the plurality of heat-conducting protrusions are arranged at intervals along a circumferential direction of the inner tube.

11. The furnace according to claim 9, wherein one end of the plurality of heat-conducting protrusions extends to a gas inlet end of the inner tube, another of the plurality of heat-conducting protrusions extends to a gas outlet end of the inner tube.

12. The furnace according to claim 2, wherein an outer surface of the outer tube is provided with a second inlet and a second outlet, the second inlet and the second outlet are respectively connected to the first gap, the second inlet is located lower than the second outlet.

13. The furnace according to claim 12, wherein the first heat exchanger, along an extension direction thereof, comprises a first connecting section, a second connecting section, and a main body section between the first connecting section and the second connecting section, the first connecting section is connected to the first gas outlet, the second connecting section is connected to the second gas inlet, the second gas inlet is located lower than the first gas outlet, the second inlet is arranged on the second connecting section, and the second outlet is arranged on the first connecting section.

14. The furnace according to claim 13, wherein one end of the furnace body is provided with a furnace door, another end of the furnace body is provided with the first gas outlet;
the main body section extends toward a peripheral side of the furnace body.

15. The furnace according to claim 14, wherein central axes of each of the first connecting section and the second connecting section are noncoplanar straight lines, an extension direction of the second connecting section is perpendicular with an extension direction of the first connecting section.

16. The furnace according to claim 1, wherein an outer peripheral wall of the furnace body is provided with a plurality of first gas inlets, the plurality of first gas inlets are arranged at intervals along a length direction of the furnace body, each of the plurality of first gas inlets is connected to the heat exchange gas channel.

17. The furnace according to claim 1, further comprising a suction device, wherein the suction device is connected to the heat exchange device and an outlet of the gas flow channel, a suction flow rate of the suction device is greater than a gas inlet flow rate of the first gas inlet.

18. The furnace according to claim 2, further comprises a cooling medium source for outputting the cooling medium, wherein the cooling medium source comprises a first output port and a second output port, the first output port is connected to the heat exchange tube, the second output port is connected to the first gap.

19. A semiconductor processing equipment comprising:
a furnace comprising:
a furnace body comprising a furnace tube and an insulation layer disposed around the furnace tube, a heat exchange gas channel formed between an outer wall of the furnace tube and the insulation layer, the heat exchange gas channel comprising a first gas inlet and a first gas outlet;
a heat exchange device comprising a gas flow channel and a cooling channel, the gas flow channel connected to the first gas outlet, the cooling channel configured to provide a cooling medium for exchanging heat with a gas in the gas flow channel; and
a gas supply system connected to the first gas inlet and configured to supply heat exchange gas into the heat exchange gas channel through the first gas inlet.

20. The semiconductor processing equipment according to claim 19, wherein the gas supply system comprises a gas source and a gas supply line, the gas supply line is connected between the gas source and the first gas inlet, the gas source is configured to provide the heat exchange gas into the heat exchange gas channel through the gas supply line.
